(19) United States
(12) Patent Application Publication
(10) Pub. No.: US 2014/0287571 A1
(43) Pub. Date: Sep. 25, 2014

(54) DOUBLE-ACTIVE-LAYER STRUCTURE WITH A POLYSILICON LAYER AND A MICROCRYSTALLINE SILICON LAYER, METHOD FOR MANUFACTURING THE SAME AND ITS APPLICATION

(71) Applicant: INNOLUX CORPORATION, Miao-Ly County (TW)

(72) Inventors: Hanson Liu, MIAO-LI COUNTY (TW); Ryan Lee, MIAO-LI COUNTY (TW)

(21) Appl. No.: 14/297,366

(22) Filed: Jun. 5, 2014

Related U.S. Application Data
(62) Division of application No. 12/336,093, filed on Dec. 16, 2008.

(30) Foreign Application Priority Data
Feb. 5, 2008 (TW) 097104490

(51) Int. Cl. H01L 21/02

(52) U.S. Cl. CPC H01L 21/02595; H01L 21/02532; H01L 21/02675
USPC 438/487

(57) ABSTRACT

A first amorphous silicon layer is formed over a substrate and a second amorphous silicon layer is formed over the first amorphous silicon layer. When a laser annealing process is performed, the second amorphous silicon layer absorbs more laser light than the first amorphous silicon layer does. The first amorphous silicon layer crystallizes into a microcrystalline silicon layer and the second amorphous silicon layer crystallizes into a polysilicon layer. During the laser annealing process, light interference between the first amorphous silicon layer and an underlying buffer layer is eliminated owing to that the second amorphous silicon layer absorbs more laser light. The laser fringe is eliminated. The microcrystalline silicon layer with better crystalline uniformity can serve as an active layer for TFTs in the display area of an OLED display to improve its illumination uniformity.

### RELATED APPLICATIONS

This application is a divisional application of U.S. patent application Ser. No. 12/336,093, filed Dec. 16, 2008, which itself claims the priority benefit of Taiwan Application Serial Number 097104490, filed on Feb. 5, 2008. The entirety of the above-mentioned patent applications is hereby incorporated by reference herein and made a part of specification.

### BACKGROUND OF THE INVENTION

1. Field of the Invention

The present invention relates to a thin film transistor (TFT) display and to a method for manufacturing the same; more particularly, the present invention relates to a TFT display having a double-active-layer structure with a polysilicon layer and a microcrystalline silicon layer, and to a method for manufacturing the same.

2. Description of the Related Art

In a conventional method for manufacturing an organic light-emitting diode (OLED) display, a buffer layer is usually formed over a substrate prior to the deposition of an amorphous silicon active layer. This advance step is to prevent the impurities in the glass substrate from diffusing into the active layer during the subsequent excimer laser annealing (ELA) process, by which an amorphous silicon active layer can crystallize into a polysilicon active layer. When long-wavelength laser of a wavelength longer than 400 nm is used in the ELA process, the laser light will transmit through the amorphous silicon active layer. As a result, some of the laser light will be reflected back to the amorphous silicon layer, causing the polysilicon crystals crystallized from the amorphous silicon to have various grain sizes. The various grain sizes, nonetheless, will affect the quality of the channel region of a thin film transistor (TFT) that is subsequently formed in the display area of an OLED display. For the OLED display, the illumination uniformity is determined by the current density flowing through every OLED unit, while the current density is determined by the quality of the channel region of each TFT that drives the OLED unit. That is to say, the above ELA process tends to affect the quality of the channel region of subsequently formed TFTs, further affecting the current density flowing through every OLED unit. This may result in poor illumination uniformity of the OLED display. To reduce the influence of buffer layer associated with laser light, which means to reduce the interference of laser light between the amorphous silicon layer and the buffer layer, adjusting the thickness of the buffer layer is generally adopted in a conventional process. However, the improvement brought by such method is only modest.

### SUMMARY OF THE INVENTION

An objective of the present invention is to provide a double-active-layer structure with a polysilicon layer and a microcrystalline silicon layer and a method for manufacturing the same, in which two amorphous silicon layers are formed over a substrate, and during a laser annealing process, an upper amorphous silicon layer absorbs more laser light, so that interference of laser light between a lower amorphous silicon layer and an underlying buffer layer is reduced. Accordingly, interference fringes of laser light can be reduced.

Another objective of the present invention is to provide a double-active-layer structure with a polysilicon layer and a microcrystalline silicon layer to be used in an OLED display, wherein the microcrystalline silicon layer can serve as an active layer of TFTs in the display area to improve illumination uniformity thereof, while the polysilicon layer can serve as an active layer of TFTs in the driving circuit area.

To achieve the above objectives, the method for manufacturing a double-active-layer structure with a polysilicon layer and a microcrystalline silicon layer of the present invention begins with providing a substrate. Next, a first amorphous silicon layer is formed over the substrate. By patterning the first amorphous silicon layer, a first active layer, which includes the patterning first amorphous silicon layer, is formed on the substrate. A first insulating layer is then formed over the first active layer and over the part of the substrate that is not covered by the first active layer. Next, a second amorphous silicon layer is formed over the first insulating layer. A laser annealing process is performed, making the first amorphous silicon layer crystallize into a microcrystalline silicon layer and the second amorphous silicon layer into a polysilicon layer. By patterning the polysilicon layer, a second active layer is formed on the part of the substrate uncovered by the first active layer. The grain sizes in the microcrystalline silicon layer are smaller than those in the polysilicon layer.

In addition, the present invention provides a TFT display having a double-active-layer structure with a polysilicon layer and a microcrystalline silicon layer, which comprises: a substrate including a display area and a driving circuit area; a plurality of first TFTs formed in the display area on the substrate, each first TFT having a microcrystalline silicon channel layer; and a plurality of second TFTs formed in the driving circuit area on the substrate, each second TFT having a polysilicon channel layer.

The TFT display of the present invention can be an OLED display. By forming TFTs having microcrystalline silicon channel regions in the display area, illumination uniformity thereof can be improved.

Moreover, the present invention provides an electronic device, which includes an image display system comprising a display device and an input unit. The display device, to which the input unit is coupled, has a TFT display having the double-active-layer structure with a polysilicon layer and a microcrystalline silicon layer of this invention. Signals are sent by the input unit to the display device to control its display of images.

### BRIEF DESCRIPTION OF THE DRAWINGS

FIGS. 1A through 1H are schematic cross-sectional views respectively corresponding to various stages of manufacturing a TFT display having a double-active-layer structure with a polysilicon layer and a microcrystalline silicon layer of the present invention.

### DETAILED DESCRIPTION OF THE PREFERRED EMBODIMENTS

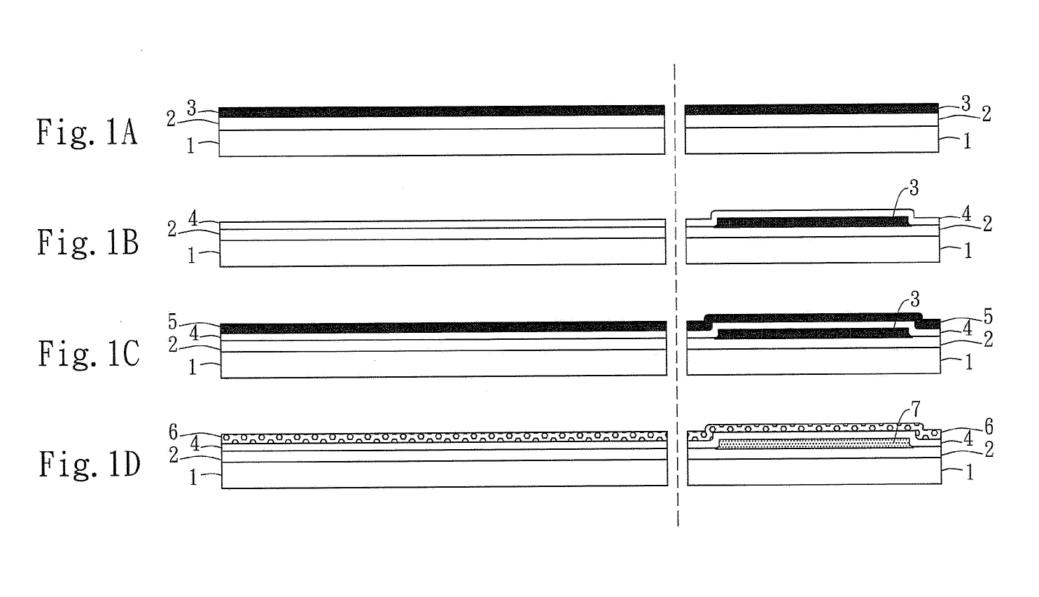

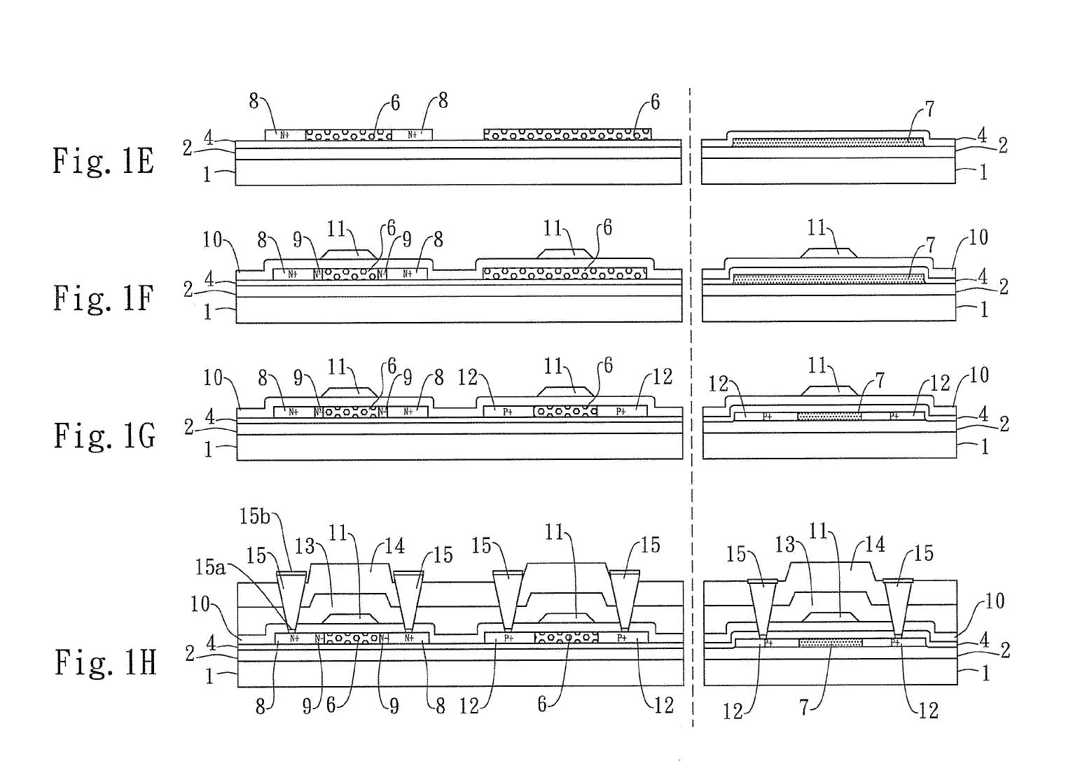

FIGS. 1A through 1D are schematic cross-sectional views respectively corresponding to various stages of manufacturing a double-active-layer structure with a polysilicon layer and a microcrystalline silicon layer of the present invention. Referring to FIG. 1A, a substrate 1, such as a glass substrate or other semiconductor substrate, is provided first. A display area is defined on the right side surface of the substrate 1, and a driving circuit area is defined on the left side surface thereof. A buffer layer 2 is formed over the substrate 1, and next, a first amorphous silicon layer 3 is formed over the buffer layer 2. Referring to FIG. 1B, by patterning the first amorphous silicon layer 3, a first active layer is formed in the display area on the substrate 1. The first active layer includes the patterning first amorphous silicon layer 3. A first insulating layer 4 is then formed over the first active layer, and over the part of the substrate 1 that is not covered by the first active layer also. Materials used to form the first insulating layer 4 can include silicon dioxide or silicon nitride. Referring to FIG. 1C, a second amorphous silicon layer 5 is formed over the first insulating layer 4. Referring to FIG. 1D, a laser annealing process is performed, the second amorphous silicon layer 5 absorbs more laser light and crystallizes into a polysilicon layer 6; the first amorphous silicon layer 3, on the other hand, absorbs less laser light and crystallizes into a microcrystalline silicon layer 7.

In the present invention, laser with a wavelength longer than 400 nm is used during the laser annealing process. Most laser is absorbed by the second amorphous silicon layer 5, while a small part of the laser transmits through the second amorphous silicon layer 5 and is absorbed by the first amorphous silicon layer 3. In other words, the second amorphous silicon layer 5 absorbs more laser light than the first amorphous silicon layer 3 does, and crystallizes into the polysilicon layer 6 with larger-sized grains. The polysilicon layer 6 is favorable for forming a CMOS driving circuit in the driving circuit area. And the microcrystalline silicon layer 7, with better uniformity in its crystalline structure, is favorable for forming a driving TFT, such as a driving TFT of an active matrix OLED, in the display area. The crystallized microcrystalline silicon layer 7 contains grain sizes ranging from 0.01 to 0.1 μm, and the crystallized polysilicon layer 6 contains grain sizes ranging from 0.1 to 0.5 μm. Moreover, the laser with such a wavelength can be absorbed by both of the second amorphous silicon layer 5 and the first amorphous silicon layer 3, further reducing the interference of laser light between the buffer layer 2 and the first amorphous silicon layer 3.

In addition, the double-active-layer structure with a polysilicon layer and a microcrystalline silicon layer of the present invention can be achieved by forming a microcrystalline silicon layer (corresponding to the microcrystalline silicon layer 7) first on the buffer layer 2 of the display area. Then, the first insulating layer 4 is formed over the microcrystalline silicon layer of the display area, and over the buffer layer 2 of the driving circuit area as well. Next, an amorphous silicon layer (corresponding to the second amorphous silicon layer 5) is formed over the first insulating layer 4. A laser annealing process is then performed with short-wavelength laser of a wavelength shorter than 400 nm, crystallizing the amorphous silicon layer into a polysilicon layer. Through the above steps, the double-active-layer structure with a polysilicon layer and a microcrystalline silicon layer of the present invention can also be achieved.

The double-active-layer structure of the present invention, whose schematic cross-sectional view as shown in FIG. 1D, can be applied to manufacture a TFT display. FIGS. 1E through 1H are schematic cross-sectional views corresponding to various stages of manufacturing a TFT display subsequent to forming the double-active-layer structure in FIG. 1D. FIG. 1H shows a schematic cross-sectional view of the completed TFT display manufactured with the method of this invention.

Referring to FIG. 1E, by patterning the polysilicon layer 6, a second active layer is formed on the substrate 1 of the driving circuit area. A high concentration N-type doping is then carried out to form a plurality of N⁺ source/drains 8 at the second active layer of the driving circuit area. Referring to FIG. 1F, a low concentration N-type doping is carried out to form a lightly doped N⁻ source/drain 9 between each N⁺ source/drain 8 and its adjacent polysilicon layer 6. Next, a second insulating layer 10 is formed over the second active layer and the first insulating layer 4. Materials used to form the second insulating layer 10 can include silicon dioxide or silicon nitride. In the driving circuit area, the second insulating layer 10 serves as the gate insulating layer for a plurality of TFTs subsequently formed, whereas in the display area, the second insulating layer 10 together with the first insulating layer 4 serves as the gate insulating layer for a plurality of TFTs subsequently formed. Then, a plurality of gate electrodes 11 are formed on the second insulating layer 10, at positions corresponding to the first active layers and the second active layers respectively. At this stage, a plurality of N-type TFTs are successfully formed in the driving circuit area on the substrate 1, with each N-type TFT having a polysilicon channel region that is formed of the polysilicon layer 6. Referring to FIG. 1G, a high concentration P-type doping is carried out. A plurality of P⁺ source/drains 12 are formed at the second active layer of the driving circuit area where N-type TFTs are not formed. And a plurality of P⁺ source/drains 12 is formed at the first active layer of the display area. At this stage, a plurality of P-type TFTs are successfully formed in the driving circuit area, with each P-type TFT having a polysilicon channel region that is formed of the polysilicon layer 6; besides, a plurality of P-type TFTs are successfully formed in the display area, with each P-type TFT having a microcrystalline silicon channel region that is formed of the microcrystalline silicon layer 7. The circuit driving area thus contains a plurality of CMOS driving circuits consisting of the N-type TFTs and P-type TFTs, both of which have polysilicon channel regions; on the other hand, the display area contains a plurality of P-type TFTs having microcrystalline silicon channel regions. Moreover, the TFTs of the driving circuit area comprise the gate insulating layer, which is formed of the second insulating layer 10; the TFTs of the display area comprise the gate insulating layer, which is formed of the second insulating layer 10 together with the first insulating layer 4. Referring to FIG. 1H, a third insulating layer 13 is formed over the N-type TFTs and the P-type TFTs; a passivation layer 14 is then formed over the third insulating layer 13. Next, a plurality of conductive contacts 15 is formed. Each of the conductive contacts 15 passes through the passivation layer 14 and the third insulating layer 13 to contact the corresponding N⁺ source/drain 8 or P⁺ source/drain 12, so that they can be electrically connected to an external power source. A conductive bottom pad 15a may be formed at the bottom of each conductive contact 15 to enhance its adhesion to the underneath N⁺ source/drain 8 or P⁺ source/drain 12. Likewise, a conductive top pad 15b can be formed at the top of each conductive contact 15 to enhance its adhesion to a subsequently formed solder bump (not shown) above.

In the above method of this invention, a plurality of P-type TFTs having microcrystalline silicon channel regions are formed in the display area; however, N-type TFTs having microcrystalline silicon channel regions can be substituted for the P-type ones. Compared with the P-type TFTs having polysilicon channel regions in the driving circuit area, the P-type TFTs having microcrystalline silicon channel regions in the display area contain smaller grain sizes in the channel region, and will have a larger sub-threshold swing. In addition, since the gate insulating layer in the P-type TFTs having microcrystalline silicon channel regions in the display area is thicker than that in the P-type TFTs having polysilicon channel regions in the driving circuit area, the former P-type TFTs will have a larger sub-threshold swing as well.

Moreover, the TFTs having microcrystalline silicon channel regions and the TFTs having polysilicon channel regions that are manufactured according to the above method for manufacturing a TFT display can also be applied to the manufacture of an ambient light sensor. The TFTs having microcrystalline silicon channel regions can serve as the sensor transistors of the ambient light sensor, while the TFTs having polysilicon channel regions can serve as the driving circuit transistors thereof.

The TFT display manufactured according to the method of the present invention can be an OLED display. With each P-type TFT having microcrystalline silicon channel regions serving as the switch transistor for each OLED unit corresponding to each pixel, the current density flowing through each OLED unit can be controlled. Since the channel region of the P-type TFT having microcrystalline silicon channel regions consists of smaller, more uniform grains, the quality of the channel region is improved. As a result, better uniformity of current densities flowing through the OLED units can be achieved, leading the OLED units to produce more uniform illumination. To sum up, when a TFT display of the present invention is applied to an OLED display, the illumination uniformity can be improved.

The TFT display of the present invention can also be applied to an image display system that is integrated into an electronic device. The image display system can include a display device and an input unit, with the display device comprising the TFT structure according to the present invention. The input unit is coupled to the display device, and signals are sent by the input unit to the display device to control its display of images.

The electronic devices can include but not limited to a cellular phone, digital camera, PDA, notebook computer, desktop computer, television, automotive display, aircraft display, digital photo frame, GPS receiver, or portable DVD player.

While this invention has been described by way of examples and in terms of preferred embodiments, it is to be understood that this invention is not limited thereto, and that various changes, substitutions, and alterations can be made herein without departing from the spirit and scope of this invention as defined by the appended claims.

What is claimed is:

1. A method for manufacturing a double-active-layer structure with a polysilicon layer and a microcrystalline silicon layer, including:
providing a substrate;
forming a first amorphous silicon layer on the substrate;
patterning the first amorphous silicon layer to form a amorphous silicon active layer on the substrate;
forming a first insulating layer over the amorphous silicon active layer and over the part of the substrate uncovered by the amorphous silicon active layer;
forming a second amorphous silicon layer over the first insulating layer;
performing a laser annealing process to crystallize the amorphous silicon active layer into a microcrystalline silicon active layer and to crystallize the second amorphous silicon layer into a polysilicon layer; and
patterning the polysilicon layer to form a polysilicon active layer on the part of the substrate uncovered by the microcrystalline silicon active layer.

2. The method of claim 1, wherein the laser annealing process is performed with a wavelength longer than 400 nm.

3. The method of claim 1, wherein the grain sizes in the microcrystalline silicon layer range from 0.01 to 0.1 μm.

4. The method of claim 1, wherein the grain sizes in the polysilicon layer range from 0.1 to 0.5 μm.

5. A method for manufacturing a double-active-layer structure with a polysilicon layer and a microcrystalline silicon layer, including:
providing a substrate and defining a first area and a second area on the substrate;
forming a microcrystalline silicon active layer in the first area on the substrate;
forming an insulating layer over the microcrystalline silicon active layer and over the substrate corresponding to the second area;
forming an amorphous silicon layer over the insulating layer;
performing a laser annealing process to crystallize the amorphous silicon layer into a polysilicon layer; and
patterning the polysilicon layer to form a polysilicon active layer in the second area.

6. The method of claim 5, wherein the laser annealing process is performed with a wavelength less than 400 nm.

7. The method of claim 5, wherein grain sizes in the microcrystalline silicon layer range from 0.01 to 0.1 μm.

8. The method of claim 5, wherein the grain sizes in the polysilicon layer range from 0.1 to 0.5 μm.
